(19) United States
(12) Patent Application Publication
(10) Pub. No.: US 2007/0011588 A1
(43) Pub. Date: Jan. 11, 2007

(54) Architecture and method for error detection and correction for data transmission in a network

(76) Inventor: David Shiung, Tainan City (TW)

Correspondence Address: J C PATENTS, INC., 4 VENTURE, SUITE 250, IRVINE, CA, 92618, US

(21) Appl. No.: 11/206,495

(22) Filed: Aug. 17, 2005

(30) Foreign Application Priority Data
Jun. 6, 2005 (TW) 94118534

(51) Int. Cl. H03M 13/00

(52) U.S. Cl. 714/776

(57) ABSTRACT

Architecture and a method for error detection and error correction for data transmission in a network are provided. In the above architecture, the data for transmission is first encoded by a generating polynomial and the generated parity bits are placed behind the data bit to be transmitted together. A packet, which is a transmitting unit, is formed from the parity bits and the transmitted data. When the packet is received at the receiving side via a transmitting channel, inspection is performed by using a parity bit checker. After inspection, if the parity bits are found to contain no error, a further decoding process is directly performed on the received packet. And if the parity bits are found to contain error, the received packet is sent to the decoder for further decoding.

### CROSS-REFERENCE TO RELATED APPLICATION

This application claims the priority benefit of Taiwan application serial no. 94118534, filed on Jun. 6, 2005. All disclosure of the Taiwan application is incorporated herein by reference.

### BACKGROUND OF THE INVENTION

1. Field of Invention

The present invention is related to an architecture and a method for cyclic code detection and correction. In particular, it is related to an architecture and a method using cyclic code for performing error detection and error correction for the application in a data transmission architecture.

2. Description of Related Art

Internet fever has swept the globe, computer networks are no longer exclusive rights belonging to the network service providers and high tech companies. In the e-Generation, home has been entered by broadband internet and gained acceptance by individual users. As more and more telecommunication service providers are joining in, mobile communication is further integrated with the internet, and the wireless networks continue to rapidly evolve and develop. Wireless transmission has further become a crucial element of the daily communication lifestyle in line with digital communication principles.

Digital communication is a signal transmission using digital signals, and a telecommunication system called the digital communication system is designed in accordance with the digital signal transmission. Telex telegraph, data communication, digital telephone communication, and other similar systems are all belonging to digital communication. The digital communication includes a signal source and a signal destination. The signal source is the origin of the message being transmitted, and the signal destination is the final receiving side of the message, which can be in the form of a person or machine. During the encoding and decoding of the signal source, whether the analog signal sent from the source is continuous or discrete, it goes through source encoding to be sampled, quantified, and encoded to change into a digital signal. As a whole, source encoding has two main functions: one is for analog to digital conversion; and the other is for the reduction of the error code rate for the signal. Source decoding is the reverse processing of the source encoding.

However, during transmitting channel encoding and decoding, the transmission medium is the channel, which is often affected by noise interference. The terminal device also contains noise in itself. Signal distortion may occur at each of the segments of the telecommunication system. The receiving of digital signal errors and the forming of error codes are possibly caused by signal interference from the noises and signal distortions. Simply stated, the signal codeword bit, because of having the channel under non-ideal conditions and noise interferences during the transmission process, at the receiving side is caused to have error codes while the reproduced codeword bit is differentiated. For the sake of automatic detection or correction of error, a conventional method is by the adoption of error code detection method and error correction method.

Referring to FIG. 1, it is schematically illustrating the basic elements for data transmission, which forms the general format of a data packet. A packet is the taking of the transmitted data using a fixed size and format to partition into a plurality of sub data sets. Usually, a predetermined fix-sized packet header for the data source at the receiving side is included in each packet. A plurality of parameters for packet processing is included in the packet header. In addition, the packet payload, which is the data content for transmission, is included immediately after the packet header.

Referring to FIG. 2, it is a block diagram schematically illustrating a conventional data transmission architecture. The data bit or codeword transmitted by the data source 210 is accordingly passed through the channel encoding/modulating unit 220, the transmitting channel 230, and the channel decoding/demodulating unit 240. The transmitted data is then acquired at the receiving side. For preventing the creation of the aforementioned error code during the data transmission process, inspection to the received data is typically performed to verify whether error has occurred or to perform the required correction of error. The methods include the conventional cyclic redundancy check (CRC) or the binary cyclic code.

The cyclic redundancy check (CRC) is the adding of a redundancy bit mainly in the fixed modulation method. The redundancy bit according to pre-established rules during the encoding process is added by the channel encoding/modulating unit 220, and the redundancy bit is removed by the channel decoding/demodulating unit 240 and the data transmission correctness is assessed, during the decoding process. And during the cyclic redundancy check (CRC), a shared polynomial is used for incorporating for adding redundancy. During receiving or using the data, after reading at each fixed size or a block, a CRC character or a CRC value is usually read in following. The data for calculating the polynomial results for comparing against the CRC value is needed to be used by the receiving side for verifying data correctness. In other words, the CRC code is added into the packet. Upon the packet is received by the receiving side, the correctness of the content of the packet is verified using the above CRC code.

Another processing method for data transmission, which is called the binary cyclic code processing method, is the direct correction of incorrect bits in the content of the packet using binary cyclic code for correcting data error. If the packet is unable to be corrected, it is then discarded.

In the aforementioned conventional processing method for data transmission, both data error detection and data error correction are independently and exclusively processed. However, in actual data transmission applications (such as using wireless transmission), error detection and error correction for the data are both indispensable.

### SUMMARY OF THE INVENTION

The present invention proposes an architecture and a method for the error detection and error correction for data transmission. Error detection and error correction are performed at the same time during data transmission to improve upon the deficiencies of conventional data transmission, thus effectively increase the efficiency for data transmission processing.

The present invention proposes the architecture and the method of error detection and error correction for data transmission. During decoding, the decoding process requires considerably more expenditure of complex software and hardware infrastructure than the encoding process. As a result, the present invention proposes the architecture and method for error detection and error correction for data transmission, which can effectively reduce the required complexity and cost and more effectively improve the software performance during decoding.

The present invention proposes the architecture and the method for error detection and error correction for data transmission. The transmitted data bits are first subjected to the encoding by the generating polynomial, and a plurality of formed parity bits are generated and placed behind the data bit to be transmitted together. And after the receiving side receives the data via the transmitting channel, the data is first sent to the parity bit checker for inspection. After inspection, if the parity bits have no error being found, the received data is directly transmitted to the back end process for processing. However, if the parity bits are found to contain error, the received data are transmitted again to the decoder for further decoding.

In an embodiment of the present invention, a method is proposed for the error detection and error correction for data transmission. First, a packet is received, wherein it includes the data and parity bits that are to be transmitted. The parity bits are generated by subjecting the transmitted data to a generating polynomial. And after inspection of the parity bits, if no error is found for the parity bits, the decoding operation is not performed. On the other hand, if the parity bits are found to contain an error, both decoding operation and error correction are performed.

The aforementioned method for error detection and error correction for data transmission, wherein the method for inspection of the aforementioned parity bits is by using the generating polynomial.

The aforementioned method for error detection and error correction for data transmission, wherein the transmitted data is divided by the generating polynomial, wherein the obtained remainder is the parity bits.

The aforementioned method for error detection and error correction for data transmission, wherein the method for inspection is a cyclic redundancy check method.

In an embodiment of the present invention, an architecture for error detection and error correction for data transmission is proposed. The architecture includes a transmitting side and a receiving side. The transmitting side includes an encoder, and the transmitted data is used by the encoder in accordance to a generating polynomial for forming a plurality of parity bits. And, the transmitted data, a packet header and the parity bits, which are to be transmitted, together form a packet. And the packet is transmitted through a transmitting channel. At the receiving side, a parity bit checker and a decoder are included. As the parity bit checker receives the packet, the parity bits of the packet are inspected. If no error is found for the parity bits, the decoding operation is thus not performed. However, if error is found for the parity bits, decoding operation and error correction are then performed.

The aforementioned architecture for error detection and error correction for data transmission further includes a decoder. Upon the inspection of the packet by the parity bit checker and the indication of the occurrence of error, the decoder is used to perform the decoding and error correction operation.

In the aforementioned architecture for error detection and correction for data transmission, the encoder has a plurality of single bit registers and a plurality of XOR logic gates for executing an operation on the transmitted data by dividing with the generating polynomial, wherein the obtained remainder is the parity bits.

In the aforementioned architecture for error detection and error correction for data transmission, wherein the method for the inspection of the parity bits by the parity bit checker is by means of the generating polynomial.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram schematically illustrating the basic elements for data transmission, which is also the general format of a packet.

FIG. 2 is a block diagram schematically illustrating an architecture for a conventional data transmission.

FIG. 3 is a flow chart diagram schematically illustrating an architecture for the error detection and correction for data transmission, according to an embodiment of the present invention.

FIG. 4 is a schematic diagram illustrating a packet format for the architecture for error detection and error correction for data transmission, according to the embodiment of the present invention shown in FIG. 3.

FIG. 5 is a flow chart diagram illustrating the encoding method for the channel encoding/modulating unit using a generating polynomial corresponding to the transmitted data bits, according to an embodiment of the present invention.

FIG. 6 is a block diagram schematically illustrating the packet format for the data transmission to the decoder, according to an embodiment of the present invention.

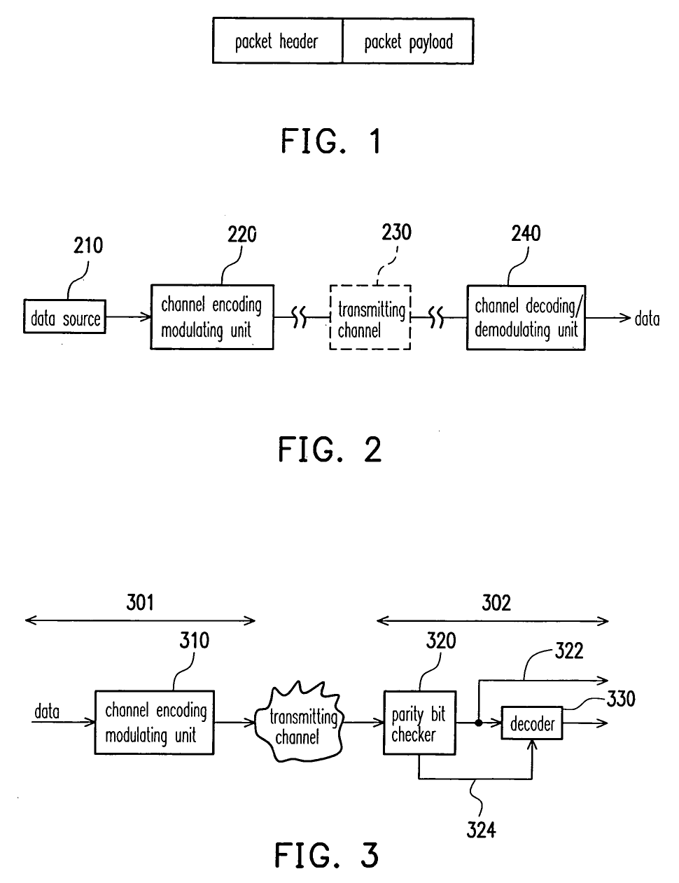

### DESCRIPTION OF THE PREFERRED EMBODIMENTS

The present invention proposes an architecture for error detection and error correction for data transmission, and the error detection for the transmitted data is performed at the same time to provide the correction when the detection of error occurs, thus improving the deficiencies for conventional data transmission and effectively increasing the efficiency for the processing of transmitted data.

In addition, because typically the cyclic redundancy check (CRC) method is used during the decoding process, which requires for expending considerably more complex software and hardware infrastructure than for encoding. Therefore, the present invention proposes the architecture and the method for error detection and error correction for data transmission that can effectively reduce the complexity and cost for decoding and further increase the software performance for decoding.

In an embodiment of the present invention, it uses the encoding/decoding of the cyclic code check method and the data correction method of the binary cyclic code in combination. A generating polynomial encoding is first undergone on the transmitted data bits, in which the data bits are divided by the generating polynomial, and the obtained remainder ( herein referred to as parity bits) are placed behind the data bits to be sent out together. After the receiving side receives the data via the transmitting channel, the data is then sent to the parity bit checker for inspection. Upon inspection, if the parity bits are found to contain no error, the received data is directly transmitted to the back end process for processing. On the other hand, if the parity bits are found to contain error, the received data is then transmitted to the decoder for decoding.

In the architecture and method for error detection and error correction for data transmission for an embodiment of the present invention, the packet error probability is typically much less than one under most transmission conditions; as a result, there is no need for decoding and correction all of the received data, thereby effectively reducing the required complexity and cost for decoding and further effectively improving the software performance for decoding.

In addition, the encoding/decoding for the aforementioned cyclic code check method can be a cyclic redundancy check (CRC) method. Furthermore, the decoder can be a CRC decoder or a syndrome decoder.

Referring to FIG. 3, it is a schematic diagram illustrating the architecture for error detection and error correction for the data transmission of an embodiment for the present invention. First, the source data is processed by the channel encoding/modulating unit 310 via the encoding modulation at the error detection and correction infrastructure at the transmitting side 301. And then the source data is transmitted out through the transmitting channel. However, at a receiving side 302, the received data is first sent to the parity bit checker 320 for inspection. After inspection, if no error is found in the parity bits, the received data is then directly taken to the back end process for processing. If an error is found in the parity bits, the received data is then sent to the decoder 330 for decoding and correction. In the architecture for data transmission, because the transmitter and receiver units included in the transmitting channel are of conventional technologies; therefore, only a schematic diagram is used for providing a brief description, and no further discussions are provided herein.

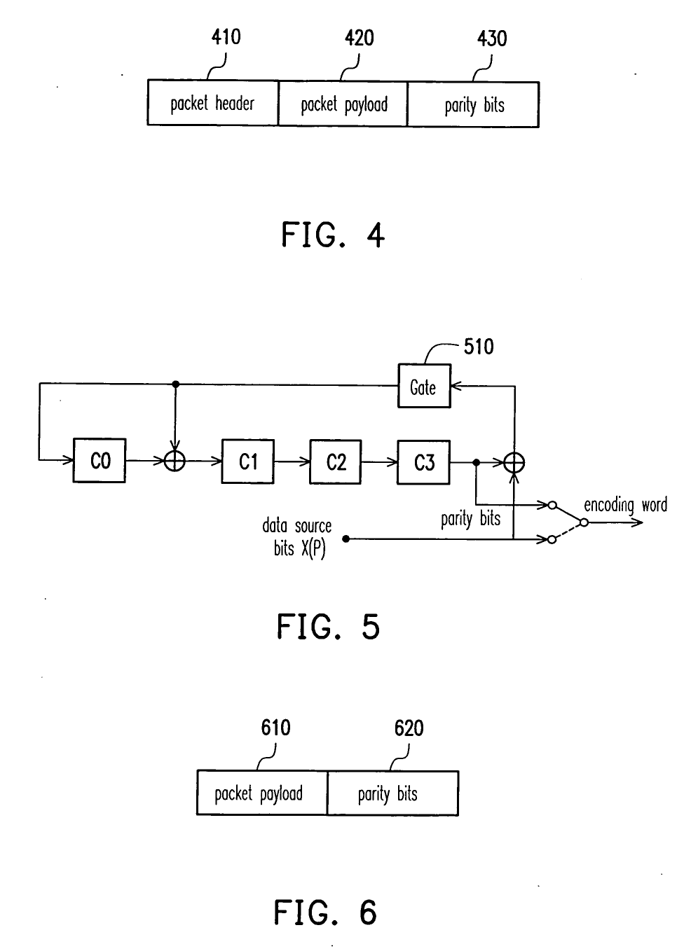

The cyclic redundancy check (CRC) method is used as an example of the aforementioned encoding/decoding method. The present invention is suitable for the use of encoding/decoding methods of other architectures; therefore, it is not limited hereto. First, the channel encoding/modulating unit 310 uses a generating polynomial to encode the transmitted data bits, which are the data bits taken to be divided by the generating polynomial and then the remainder (hereinafter referring as parity bits) taken to be placed behind the data bits for sending out together. The parity bits are suitable to be included in the transmitted data basic unit format for an embodiment of the present invention. The basic unit format for the transmitted data is a packet as referred in FIG. 4. Each packet includes a packet header 410, a packet payload 420, and a plurality of parity bits 430. The packet header 410 is mainly used for processing some of the parameter settings for the packet. The parameter settings are used as the established known values for two-way communications between the transmitting side 301 and receiving side 302. And the packet payload 420 is used for the transmission of the data content. The parity bits 430 are formed from the aforementioned generating polynomial.

With regards to the receiving side 302, after the data is received using the transmitting channel, the data is first transmitted to the parity bit checker 320 for inspection. After inspection, if the parity bits are found to contain no error, the received data is directly taken via a line 322 for transmission to the back end process for processing. If the parity bits are found to contain an error, the received data is taken via the line 322 to transmit to the decoder 330 for decoding and error correction. The parity bit checker 320 is used by the decoder 330 via the signal sent out from the line 324 to verify whether to perform the decoding and error correction operations.

The encoding method of the channel encoding/modulating unit 310 is according to the generating polynomial for the transmitted data bit referred in FIG. 5. Assuming that generating polynomial is g(p)=p⁴+p+1 and an input of the data source bits are X(p), the encoding method for the transmitted data bit corresponding to the flow chart diagram shown in FIG. 5, can be performed by the shift register, which includes four single bit registers of C3, C2, C1, and C0 and two XOR logic gates. The single bit registers C3, C2, C1, and C0 can be flip-flop units or unit-delay elements. The externally connected clock signals are connected to the single bit registers C3, C2, C1, and C0. As the clock signal is changed, the movement for the stored bits for the single bit registers is in the direction of the arrow. In addition, the gate 510 controls whether or not to perform the encoding operation. Once the encoding operation starts, the data source X(p) according to timing are input to the single bit registers C3, C2, C1, and C0. And finally, the parity bits are formed. The data source bits X(p) and the parity bits are integrated to form the packet header, the packet payload, and the parity bits inside the packet.

The decoder 330 can verify whether to perform the decoding and error correction operations, according to the signal transmitted by the parity bit checker 320 via the line 324. The architectures for the decoder 330 and for the channel encoding/modulating Unit 310 using the generating polynomial for encoding of the transmitted data bits as a whole are basically the same, which is shown in FIG. 5. The four single bit registers of C3, C2, C1, and C0 and two XOR logic gates formed as a shift register are the main parts for the channel encoding/modulating Unit 310. If the received packets are correct, the output parity bits (which are the remainder after calculation) should be “0000”. If the obtained remainder is not equal to “0000”, the received data is then sent to the decoder 330 for decoding and error correction.

The packet format for the transmission to the decoder 330 is referred in FIG. 6, which includes a packet payload 610 and a plurality of parity bits 620. The parity bits 620 received by the decoder 330 is the data of the original packet without the packet header and packet payload portions. With regard to the decoder 330, it can also process the data. For example, if the received parity bits are “1010” and the packet header is “0001”, the cyclic codes decoding required for processing by the decoder 330 is for the data of “1011”.

In summary, the present invention proposes an architecture and method for error detection and error correction for data transmission. During error detection for the transmitted data, error correction is also provided at the occurrence of error at the same time, which can improve the deficiencies for conventional data transmission and effectively improve the efficiency for data transmission. In addition, the required decoding complexity and cost are further effectively reduced, and the software performance during decoding is much effectively improved.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. An error detection and error correction method for data transmission comprising:
receiving a packet, wherein the packet comprises a transmitted data and a parity bit, wherein the parity bit is generated according to a generating polynomial in accordance with the transmitted data; and
inspecting the parity bit, wherein if the parity bit is found to contain no error, a decoding operation is not performed; but if the parity bit contains an error, the decoding operation and an error correction are performed.

2. The error detection and error correction method for data transmission according to claim 1, wherein the step of inspecting the parity bit uses the generating polynomial.

3. The error detection and error correction method for data transmission according to claim 1, wherein the parity bit is taking the transmitted data to divide by the generating polynomial, and an obtained remainder is the parity bit.

4. The error detection and error correction method for data transmission according to claim 1, wherein the step of inspecting the parity bit uses a cyclic redundancy check method.

5. An architecture for error detection and error correction for data transmission, comprising a transmitting side and a receiving side, wherein
the transmitting side comprises an encoder, the encoder uses a transmitted data, according to a generating polynomial, for generating a parity bit, and the transmitted data, a packet header and the parity bit form the packet, and the packed is transmitted through a transmitting channel; and
the receiving side comprises a parity bit checker and a decoder, when the parity bit checker receives the packet, the parity bit of the packet is inspected, wherein if the parity bit contains no error, a decoding operation is not performed;
but if the parity bit contains an error, the decoding operation and an error correction are performed.

6. The architecture for error detection and error correction for data transmission according to claim 5, further comprising:
a decoder, when the parity bit checker inspect the packet and indicates an occurrence of error, the decoder performs operations of decoding and error correction.

7. The architecture for error detection and error correction for data transmission according to claim 5, wherein the encoder comprises a plurality of single bit registers and a plurality of XOR logic gates, for dividing the transmitted data by the generating polynomial, wherein an obtained remainder is the parity bit.

8. The architecture for error detection and error correction for data transmission according to claim 5, wherein the parity bit checker inspects the parity bit, according to the generating polynomial.
